(19) United States
(12) Patent Application Publication
(10) Pub. No.: US 2017/0019990 A1
(43) Pub. Date: Jan. 19, 2017

(54) MULTILAYER CIRCUIT BOARD AND PROBE CARD INCLUDING THE SAME

(71) Applicant: Murata Manufacturing Co., Ltd., Kyoto (JP)

(72) Inventors: Tadaji Takemura, Kyoto (JP); Yoshihito Otsubo, Kyoto (JP)

(21) Appl. No.: 15/279,873

(22) Filed: Sep. 29, 2016

Related U.S. Application Data
(63) Continuation of application No. PCT/JP2015/057998, filed on Mar. 18, 2015.

(30) Foreign Application Priority Data
Mar. 31, 2014 (JP) 2014-071758

(51) Int. Cl. H05K 1/02; G01R 1/073; H05K 3/46; H05K 1/03; H05K 1/11

(52) U.S. Cl. CPC H05K 1/0298; H05K 1/0306; H05K 1/0353; H05K 1/0271; H05K 1/115; H05K 3/4688; H05K 3/4629; G01R 1/07342

(57) ABSTRACT

A multilayer circuit board includes a ceramic multilayer body that is a stack of multiple ceramic layers, a resin multilayer body on the ceramic multilayer body 2 that is a stack of multiple resin layers, conductive vias in the uppermost ceramic layer, and conductive vias in the lowermost resin layer. The upper end faces of the conductive vias are exposed on the interface between the ceramic multilayer body and the resin multilayer body. The lower end faces of the conductive vias are exposed on the interface between the ceramic multilayer body and the resin multilayer body and directly connected to the upper end faces of the conductive vias in the uppermost ceramic layer. The lower end faces of the conductive vias on the resin layer side are within the upper end faces of the conductive vias on the ceramic layer side in plan view.

This is a continuation of International Application No. PCT/JP2015/057998 filed on Mar. 18, 2015 which claims priority from Japanese Patent Application No. 2014-071758 filed on Mar. 31, 2014. The contents of these applications are incorporated herein by reference in their entireties.

### BACKGROUND

### Technical Field

The present disclosure relates to a multilayer circuit board that includes a ceramic multilayer body that is a stack of multiple ceramic layers and a resin multilayer body on the ceramic multilayer body that is a stack of multiple resin layers, and to a probe card that includes this multilayer circuit board.

As the external terminal density of semiconductor devices has been increasing in recent years, the circuit boards of probe cards for electrical testing of these semiconductor devices need to have inner wiring with increased density and fineness. Circuit boards of this type are also required to have high planarity for smooth and reliable electrical testing of semiconductor devices. Thus, circuit boards with increased density and fineness of inner wiring that also offer high planarity have been under development.

An example is a multilayer circuit board 100 according to Patent Document 1, illustrated in FIG. 10. This circuit board includes a ceramic multilayer body 101 that is a stack of multiple ceramic layers 101a and a resin multilayer body 102 that is a stack of multiple resin layers 102a (e.g., polyimide). On the top surface of the multilayer circuit board 100, there are multiple coupling electrodes 103 each connected to a probe pin. On the bottom surface of the multilayer circuit board 100 there are outer electrodes 104 corresponding respectively to the surface electrodes 103, with their pitch greater than that of the coupling electrodes 103. The coupling electrodes 103 and the respective corresponding outer electrodes 104 are coupled by wiring electrodes 105 and interlayer coupling conductors 106 formed inside the multilayer circuit board 100. This gives the multilayer circuit board 100 a rewiring structure.

In such a rewiring structure, the density of wiring electrodes 105 and interlayer coupling conductors 106 needs to be higher in the upper section of the multilayer circuit board 100, the section where the coupling electrodes 103 are present, than in the lower section, the section where the outer electrodes 104 are present, to match the terminal pitch of the semiconductor devices to be tested. The upper section of the multilayer circuit board 100 is thus a resin multilayer body 102. This multilayer body is a stack of multiple resin layers 102a that are thin films on which delicate electrode patterns can be formed, such as polyimide films. The lower section of the multilayer circuit board 100, the section where the density of wiring electrodes 105 and interlayer coupling conductors 106 need not be high, is a ceramic multilayer body 101. This multilayer body, a stack of multiple ceramic layers 101a, has higher rigidity than the resin multilayer body 102 and is easy to planarize, by polishing for example.
Patent Document 1: Japanese Unexamined Patent Application Publication No. 2011-108959 (see paragraphs 0017 to 0020, paragraphs 0037 to 0042, FIG. 1, etc.)

### BRIEF SUMMARY

This multilayer circuit board 100 has an upper section (the resin multilayer body 102) made of resin, such as polyimide, and a ceramic lower section (the ceramic multilayer body 101). In cases such as when the ambient temperature changes or a similar event occurs, this heterogeneous multilayer structure in which materials with different coefficients of linear expansion are used causes stress to occur inside the multilayer circuit board 100 as a result of the difference in the amount of thermal contraction and expansion between the ceramic multilayer body 101 and the resin multilayer body 102. In particular, when the resin multilayer body 102 is formed by stacking the resin layers 102a on a ceramic multilayer body 101 formed beforehand, residual stress occurs inside the multilayer circuit board 100 as a result of the shrinkage of the resin multilayer body 102 caused by thermal curing.

In this multilayer circuit board 100, some wiring electrodes 105 (also called electrode pads) are interposed between the ceramic multilayer body 101 and the resin multilayer body 102 to connect the interlayer coupling conductors 106 in the uppermost ceramic layer 101a to the interlayer coupling conductors 106 in the lowermost resin layer 102a. These wiring electrodes 105 have a larger area in plan view than the interlayer coupling conductors 106 in the uppermost ceramic layer 101a. This means that the formation of these wiring electrodes 105 accordingly reduces the area of contact between the ceramic layer 101a and the resin layer 102a at the interface between the ceramic multilayer body 101 and the resin multilayer body 102.

A decrease in the area of contact between the ceramic layer 101a and the resin layer 102a leads to a weakening of the adhesion between them. In cases such as when the temperature of the environment surrounding the multilayer circuit board 100 changes, therefore, the aforementioned stress resulting from the difference in the coefficient of linear expansion between the ceramic multilayer body 101 and the resin multilayer body 102 may cause delamination at the interface between the two multilayer bodies.

Made in light of the above problem, the present disclosure may reduce, for multilayer circuit boards composed of a ceramic multilayer body and a resin multilayer body thereon, the interfacial delamination of the resin and ceramic multilayer bodies.

A multilayer circuit board according to the present disclosure includes a ceramic multilayer body that is a stack of multiple ceramic layers, a resin multilayer body on the ceramic multilayer body that is a stack of multiple resin layers, a first interlayer coupling conductor in the uppermost one of the ceramic layers, and a second interlayer coupling conductor in the lowermost one of the resin layers. The upper end face of the first interlayer coupling conductor is exposed on the interface between the ceramic and resin multilayer bodies. The lower end face of the second interlayer coupling conductor is exposed on the interface between the ceramic and resin multilayer bodies and directly connected to the upper end face of the first interlayer coupling conductor. The circuit board is configured such that the lower end face of the second interlayer coupling conductor is within the upper end face of the first interlayer coupling conductor in plan view.

The upper end face of the first interlayer coupling conductor, formed in the uppermost ceramic layer, and the lower end face of the second interlayer coupling conductor, formed in the lowermost resin layer, are directly connected at the interface between the ceramic and resin multilayer bodies, and the lower end face of the second interlayer coupling conductor is within the upper end face of the first interlayer coupling conductor in plan view. As a result, the area of contact between ceramic and resin layers at the interface is increased compared with that in a known multilayer circuit board in which an electrode pad is interposed between the first and second interlayer coupling conductors. In this case, the strength of the adhesion between the ceramic and resin multilayer bodies is improved. Even if internal stress due to the difference in the coefficient of linear expansion between the ceramic and resin multilayer bodies or any other cause occurs in the multilayer circuit board, the interfacial delamination of the ceramic and resin multilayer bodies will be reduced.

The circuit board may have a circuit layer between any two of the resin layers that has a planar electrode pattern overlapping the resin multilayer body in plan view except at the periphery of the resin multilayer body. The coefficient of linear expansion of the planar electrode pattern, made of metal, is smaller than the coefficient of linear expansion of the resin layers, and this ensures, for example, smaller contraction of the resin multilayer body when an ambient temperature decreases. The smaller contraction of the resin multilayer body leads to a decrease in the stress acting on the interface between the ceramic and resin multilayer bodies, thereby reducing the interfacial delamination of the ceramic and resin multilayer bodies.

The stress that acts on the interface between the ceramic and resin multilayer bodies upon events such as cure shrinkage of the resin multilayer body is proportional to the thickness of the resin multilayer body. When a circuit layer having a planar electrode pattern is present between any two of the resin layers of the resin multilayer body, the electrode pattern serves to resist the stress the resin layer or layers above the circuit layer exert on the aforementioned interface. In this case, the relaxation of the stress that acts on the interface leads to reduced interfacial delamination of the two multilayer bodies.

The thickness of the lowermost one of the resin layers may be smaller than that of the resin layer(s) located above the circuit layer. This leads to reduced thickness of the resin layer(s) located below the circuit layer and, therefore, a further decrease in the stress that acts on the interface between the ceramic and resin multilayer bodies.

There may be a gap between the peripheral surface of the upper end portion of the first interlayer coupling conductor and the uppermost ceramic layer, and some amount of the resin of which the lowermost one of the resin layers is made may be present in the gap. In this case, the anchor effect results from the presence of the resin forming the lowermost resin layer in the gap between the uppermost ceramic layer and the peripheral surface of the upper end portion of the first interlayer coupling conductor, and improves the strength of the adhesion between the ceramic and resin multilayer bodies at their interface. As a result, the interfacial delamination of the two multilayer bodies is reduced.

The circuit board may include an electrode pad connected to the upper end face of the second interlayer coupling conductor, and the electrode pad may have a larger area than the upper end face of the first interlayer coupling conductor so that the upper end face of the first interlayer coupling conductor is within the electrode pad in plan view. This ensures that the plane of connection between the first and second interlayer coupling conductors is within the electrode pad in plan view. When the resin multilayer body shrinks upon thermal curing or experiences a similar event, thus, the stress that acts on the plane of connection between the first and second interlayer coupling conductors is relaxed by the electrode pad, which is located right above this plane of connection. As a result, the reliability of the connection between the first and second interlayer coupling conductors is improved.

The largest width of the lower end face of the second interlayer coupling conductor may be greater than the thickness of the lowermost one of the resin layers. The stress that acts on the plane of connection between the first and second interlayer coupling conductors upon events such as the shrinkage of the resin multilayer body caused by thermal curing increases proportionally with the height of the second interlayer coupling conductor. The strength of the connection between the two interlayer coupling conductors is proportional to the area of connection. This means that when the height of the second interlayer coupling conductor is greater than the largest width of the plane of connection between the first and second interlayer coupling conductors, a parameter corresponding to the area of connection, the risk of fracture at the joint between the first and second interlayer coupling conductors is high. Making the largest width of the lower end face of the second interlayer coupling conductor, i.e., the largest width of the area of connection between the first and second interlayer coupling conductors, greater than the thickness of the lowermost resin layer, which is substantially equal to the height of the second interlayer coupling conductor, leads to reduced risk of fracture in the joint between the first and second interlayer coupling conductors.

The second interlayer coupling conductor may have a larger area at the lower end face thereof than at the upper end face thereof. This increases the area of connection between the first and second interlayer coupling conductors. As a result, the interfacial delamination of the ceramic and resin multilayer bodies is reduced, and the reliability of the connection between the first and second interlayer coupling conductors is improved at the same time.

A probe card according to the present disclosure includes this multilayer circuit board and is configured such that it tests electrical characteristics of semiconductor devices. It is possible to test electrical characteristics of semiconductor devices in recent years, which have tightly pitched external terminals, and the interfacial delamination of ceramic and resin multilayer bodies, a disadvantage that is encountered when a multilayer circuit board is composed of these two multilayer bodies, is reduced at the same time.

The present disclosure improves the strength of the adhesion between the ceramic and resin multilayer bodies by increasing the area of contact between the ceramic and resin layers at the aforementioned interface as compared with that in a known multilayer circuit board in which an electrode pad is interposed between the first and second interlayer coupling conductors. Furthermore, even if internal stress due to the difference in the coefficient of linear expansion between the ceramic and resin multilayer bodies or any other cause occurs in the multilayer circuit board, the interfacial delamination of the ceramic and resin multilayer bodies will be reduced by virtue of the improved strength of the adhesion between the two multilayer bodies.

### BRIEF DESCRIPTION OF THE SEVERAL VIEWS OF THE DRAWINGS

FIG. 1 is a cross-sectional view of a multilayer circuit board according to Embodiment 1 of the present disclosure.

FIG. 2 is a cross-sectional view of a multilayer circuit board according to Embodiment 2 of the present disclosure.

FIG. 3 is a cross-sectional view of a multilayer circuit board according to Embodiment 3 of the present disclosure.

FIG. 4 is a cross-sectional view of a multilayer circuit board according to Embodiment 4 of the present disclosure.

FIG. 5 is a plan view of the predetermined circuit layer in FIG. 4.

FIG. 6 is a cross-sectional view of a multilayer circuit board according to Embodiment 5 of the present disclosure.

FIG. 7 is a partial cross-sectional view of a multilayer circuit board according to Embodiment 6 of the present disclosure.

FIG. 8 is a cross-sectional view of a multilayer circuit board according to Embodiment 7 of the present disclosure.

FIGS. 9A-9C present diagrams for illustrating a method for the production of the ceramic multilayer body in FIG. 8.

FIG. 10 is a cross-sectional view of a known multilayer circuit board.

### DETAILED DESCRIPTION

### Embodiment 1

A multilayer circuit board 1a according to Embodiment 1 of the present disclosure is described with reference to FIG. 1. FIG. 1 is a cross-sectional view of the multilayer circuit board 1a.

The multilayer circuit board 1a according to this embodiment includes, as illustrated in FIG. 1, a ceramic multilayer body 2 that is a stack of multiple ceramic layers 3 and a resin multilayer body 4 on the ceramic multilayer body 2 that is a stack of multiple resin layers 4a. This circuit board is used as, for example, the circuit board of a probe card that tests electrical characteristics of semiconductor devices.

The ceramic layers 3 are each composed of a substrate layer 3a, a layer of a low-temperature co-fired ceramic (LTCC) in which major components are materials such as borosilicate glass, alumina, and silica, and an anti-shrink layer 3b that controls the shrinkage of the substrate layer 3a in the direction of its main surfaces. In this case, the ceramic multilayer body 2 can be fired at 1000° C. or less, and thus the materials for the wiring electrodes and conductive vias 9a formed inside the ceramic multilayer body 2 can be low-resistance metals, such as Ag and Cu. The substrate layers 3a may optionally be layers of a high-temperature fired ceramic (HTCC).

The anti-shrink layers 3b are each made of a ceramic material (containing a glass component) that does not sinter at the sintering temperature of the ceramic material of which the substrate layers 3a are made (for example, 800° C. to 1000° C. for LTCCs). These layers prevent the substrate layers 3a from shrinking in the direction of their main surfaces during the firing of the ceramic multilayer body 2. Providing an anti-shrink layer 3b in each ceramic layer 3 in this way leads to improved accuracy of the positions of the conductive vias 9a formed in the ceramic multilayer body 2 because the anti-shrink layers 3b control the shrinkage of the ceramic layers 3 in the direction of their main surfaces during the firing of the ceramic multilayer body 2. As a result, directly connecting the conductive vias 9a in the uppermost ceramic layer 3 to the conductive vias 9b in the lowermost resin layer 4a is easy without large-area electrode pads such as those that have hitherto been used.

The resin layers 4a of the resin multilayer body 4 are each made of, for example, resin, such as polyimide. In this embodiment, these layers are stacked on the ceramic multilayer body 2 after the firing of the ceramic multilayer body 2.

This multilayer circuit board 1a has multiple top electrodes 5 on the top surface of the uppermost resin layer 4a, which is the top surface of the circuit board, and multiple bottom electrodes 6 corresponding to the top electrodes 5 on the bottom surface of the lowermost ceramic layer 3a, which is the bottom surface of the circuit board. On the surface of each of the top electrodes 5 and the bottom electrodes 6 there is a Ni/Au electrode 7 formed by plating. The top electrodes 5 and the respective corresponding bottom electrodes 6 are coupled by wiring electrodes and conductive vias 9a and 9b formed inside the multilayer circuit board 1a. The pitch of the bottom electrodes 6 is wider than that of the top electrodes 5, and there is a rewiring structure inside the multilayer circuit board 1a.

Specifically, the ceramic multilayer body 2 has circuit layers 8a between adjacent ceramic layers 3, the circuit layers having wiring electrodes, and multiple conductive vias 9a connect predetermined vertically contiguous wiring electrodes together in each of the ceramic layers 3. Likewise, the resin multilayer body 4 has circuit layers 8b between adjacent resin layers 4a, the circuit layers having wiring electrodes, and multiple conductive vias 9b connect predetermined vertically contiguous wiring electrodes together in each of the resin layers 4a.

The upper end faces of the conductive vias 9a in the uppermost ceramic layer 3 are exposed on the interface between the ceramic multilayer body 2 and the resin multilayer body 4, and the lower end faces of the conductive vias 9b in the lowermost resin layer 4a are exposed on the same interface. At the interface between the two multilayer bodies 2 and 4, the upper end faces of predetermined conductive vias 9a in the uppermost ceramic layer 3 are directly connected to the lower end faces of conductive vias 9b in the lowermost resin layer 4a.

The lower end faces of the conductive vias 9b in the lowermost resin layer 4a are within the upper end faces of the connected conductive vias 9a in the uppermost ceramic layer 3 in plan view (viewed in a direction perpendicular to the top surface of the uppermost resin layer 4a). In this way, each of the conductive vias 9a in the uppermost ceramic layer 3 corresponds to a “first interlayer coupling conductor” according to the present disclosure, and each of the conductive vias 9b in the lowermost resin layer 4a corresponds to a “second interlayer coupling conductor” according to the present disclosure. The conductive vias 9a and 9b inside the multilayer circuit board 1a can be replaced with known conductors for connecting layers, such as metal pins or electrode posts.

The largest width W1 of the lower end faces of the conductive vias 9b in the lowermost resin layer 4a can be greater than the thickness W2 of the lowermost resin layer 4a (W1>W2). The stress that acts on the plane of connection between a conductive via 9a in the uppermost ceramic layer 3 and a conductive via 9b in the lowermost resin layer 4a upon events such as the shrinkage of the resin multilayer body 4 caused by thermal curing increases proportionally with the height of the conductive via 9b located on the resin layer 4a side. The strength of the connection between the two conductive vias 9a and 9b is proportional to the area of connection. This means that when the height of the conductive via 9b on the resin layer 4a side is greater than the largest width of the plane of connection between the two conductive vias 9a and 9b, a parameter corresponding to the area of connection, the risk of fracture at the joint between the two conductive vias 9a and 9b is high. Making the largest width W1 of the lower end face of the conductive via 9b formed in the lowermost resin layer 4a, i.e., the largest width of the area of connection, greater than the thickness of the lowermost resin layer 4a, which usually is substantially equal to the height of the conductive via 9b in the lowermost resin layer 4a, leads to reduced risk of fracture in the aforementioned joint.

A probe card according to the present disclosure is composed of this multilayer circuit board 1a and probe pins mounted on the top electrodes 5 individually. This probe card tests electrical characteristics of semiconductor devices by making contact to the terminal terminals to the devices with the probe pins.

### (Method for Producing the Multilayer Circuit Board)

The following describes a method for the production of the multilayer circuit board 1a. This multilayer circuit board 1a is obtained by firing a stack of ceramic layers 3 to form a ceramic multilayer body 2 and then placing a resin multilayer body 4.

A specific description is as follows. First, a low-temperature co-fired ceramic is formed into multiple ceramic green sheets (substrate layers 3a). Anti-shrink layers 3b in the form of paste in which the major component is a flame-retardant powder, such as a powder of alumina or zirconia, are applied to (placed on) the substrate layers 3a, by screen printing for example, and dried. In this way, the ceramic layers 3 are prepared individually.

Then each ceramic layer 3 is perforated with through-holes, using a laser for example, at the points where conductive vias 9a are to be formed, and a known method is followed to form the conductive vias 9a. Then circuit layers 8a having wiring electrodes are formed, such as by screen printing using a conductor paste that contains metal, e.g., Ag or Cu. The prepared ceramic layers 3 are stacked, and the resulting stack is pressure-fired to give a ceramic multilayer body 2.

Then the top and bottom surfaces of the ceramic multilayer body 2 are polished and ground. After the pressure firing of the stack of the ceramic layers 3, the conductive vias 9a can stick out of the top and bottom surfaces of the ceramic multilayer body 2. In such a case, the reliability of the connection between the conductive vias 9a in the uppermost ceramic layer 3 and the conductive vias 9b in the lowermost resin layer 4a is affected. Removing the protrusions of the conductive vias 9a on the ceramic layer 3 side by polishing and grinding each surface of the ceramic multilayer body 2 therefore improves the reliability of the connection with the conductive vias 9b on the resin layer 4a side. The polishing and grinding process removes the oxide covering the top surfaces of the conductive vias 9a exposed on the top surface of the ceramic multilayer body 2, and this makes the connection even more reliable. Furthermore, the improved warpage and surface planarity of the ceramic multilayer body 2 leads to higher planarity of the resin multilayer body 4 placed on the ceramic multilayer body 2. The polishing and grinding of the bottom surface of the ceramic multilayer body 2 is optional.

Then bottom electrodes 6 are formed on the bottom surface of the ceramic multilayer body 2 in the same way as the circuit layers 8a.

Then resin, such as polyimide, is applied to the top surface of the ceramic multilayer body 2, by spin coating for example, to form the lowermost resin layer 4a. Conductive vias 9b and wiring electrodes for a circuit layer 8b are then simultaneously formed using photolithography. The conductive vias 9b and the wiring electrodes for a circuit layer 8b are individually obtained by forming an underlying Ti film, using sputtering for example, forming a Cu film on the Ti film using sputtering, again forming a resist thereon, exposing it, developing it, and then forming Cu electrodes on the Cu film using electrolytic or electroless plating. To ensure that the lower end face of each conductive via 9b is within the upper end face of the connected conductive via 9a in the uppermost ceramic layer 3 in plan view, the area of the lower end faces of the conductive vias 9b is smaller than that of the conductive vias 9a in the ceramic layer 3 and is greater than the thickness W2 of the lowermost resin layer 4a. The formation of the conductive vias 9b may be such that via holes are created by laser machining.

A circuit layer 8b and conductive vias 9b are formed in the same way for each of the other resin layers 4a, too, to give a resin multilayer body 4. The top electrodes 5 can be formed using, for example, photolithography. In this case, the top electrodes 5 are individual electrodes built by forming an underlying Ti film on the top surface of the uppermost resin layer 4a, using sputtering for example, forming a Cu film on the Ti film using sputtering, again forming a resist thereon, exposing it, developing it, and then forming Cu electrodes on the Cu film using electrolytic or electroless plating.

Lastly, Ni/Au electrodes 7 are formed on the surfaces of the top electrodes 5 and the bottom electrodes 6 by electrolytic or electroless plating to complete the multilayer circuit board 1a.

In this embodiment, therefore, the upper end faces of the conductive vias 9a in the uppermost ceramic layer 3 are directly connected to the lower end faces of the conductive vias 9b in the lowermost resin layer 4a at the interface between the ceramic multilayer body 2 and the resin multilayer body 4, and the lower end faces of the conductive vias 9b on the resin layer 4a side are within the upper end faces of the conductive vias 9a on the ceramic layer 3 side in plan view. This improves the strength of the adhesion between the ceramic multilayer body 2 and the resin multilayer body 4 by increasing the area of contact between the ceramic layer 3 and the resin layer 4a at the aforementioned interface as compared with that in a known multilayer circuit board in which electrode pads interposed between the conductive vias 9a on the ceramic layer 3 side and the conductive vias 9b on the resin layer 4a side connect the conductive vias 9a and 9b together. Furthermore, even if internal stress due to the difference in the coefficient of linear expansion between the ceramic multilayer body 2 and the resin multilayer body 4 or any other cause occurs in the multilayer circuit board 1a, the interfacial delamination of the two multilayer bodies 2 and 4 will be reduced by virtue of the improved strength of the adhesion between the two multilayer bodies 2 and 4.

The upper section of the multilayer circuit board 1a, the section on which top electrodes 5 are present, is a stack of resin layers 4a that tolerate delicate machining for wiring, such as polyimide layers (a resin multilayer body 4). A probe card composed of the multilayer circuit board 1a and probe pins mounted on the top electrodes 5 therefore supports testing of electrical characteristics of semiconductor devices in recent years, which have tightly pitched external terminals, with reduced interfacial delamination of a ceramic multilayer body 2 and a resin multilayer body 4, a disadvantage that is encountered when a multilayer circuit board 1a is composed of these two multilayer bodies 2 and 4.

### Embodiment 2

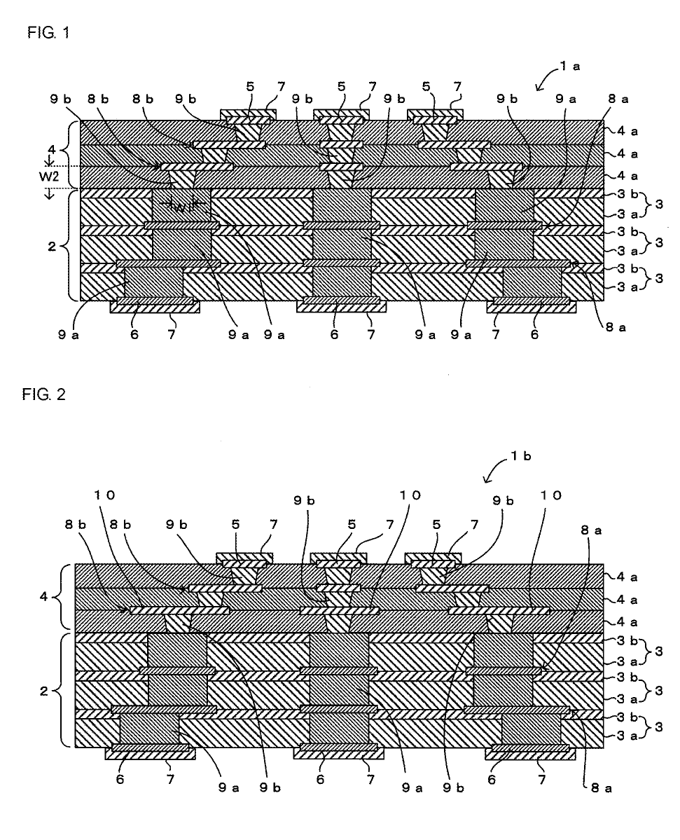

A multilayer circuit board 1b according to Embodiment 2 of the present disclosure is described with reference to FIG. 2. FIG. 2 is a cross-sectional view of the multilayer circuit board 1b.

The difference of the multilayer circuit board 1b according to this embodiment from the multilayer circuit board 1a of Embodiment 1, described with reference to FIG. 1, is that multiple electrode pads 10 connected to the conductive vias 9b in the lowermost resin layer 4a serve as wiring electrodes of the circuit layer 8b adjoining the top surface of the lowermost resin layer 4a, and that the electrode pads 10 have an area larger than the upper end faces of the conductive vias 9a in the uppermost ceramic layer 3 in plan view. The other elements are the same as those in the multilayer circuit board 1a of Embodiment 1 and thus are given the same reference numerals to avoid duplicating description.

In this case, the size of the electrode pads 10 is such that each of the upper end faces of the conductive vias 9a in the uppermost ceramic layer 3 is within an electrode pad 10 in plan view. The electrode pads 10 are made of a metal that is more rigid and has a smaller coefficient of expansion than the resin for the resin layers 4a. When the resin multilayer body 4 shrinks upon thermal curing or experiences a similar event, thus, the stress that acts on the planes of connection between the conductive vias 9a in the uppermost ceramic layer 3 and the conductive vias 9b in the lowermost resin layer 4a connected to these conductive vias 9a is relaxed by the electrode pads 10, which are located right above these planes of connection. Besides reducing the interfacial delamination of the ceramic multilayer body 2 and the resin multilayer body 4, therefore, this configuration improves the reliability of the connection between the conductive vias 9a in the uppermost ceramic layer 3 and the conductive vias 9b in the lowermost resin layer 4a, which are located at the interface between the ceramic multilayer body 2 and the resin multilayer body 4.

### Embodiment 3

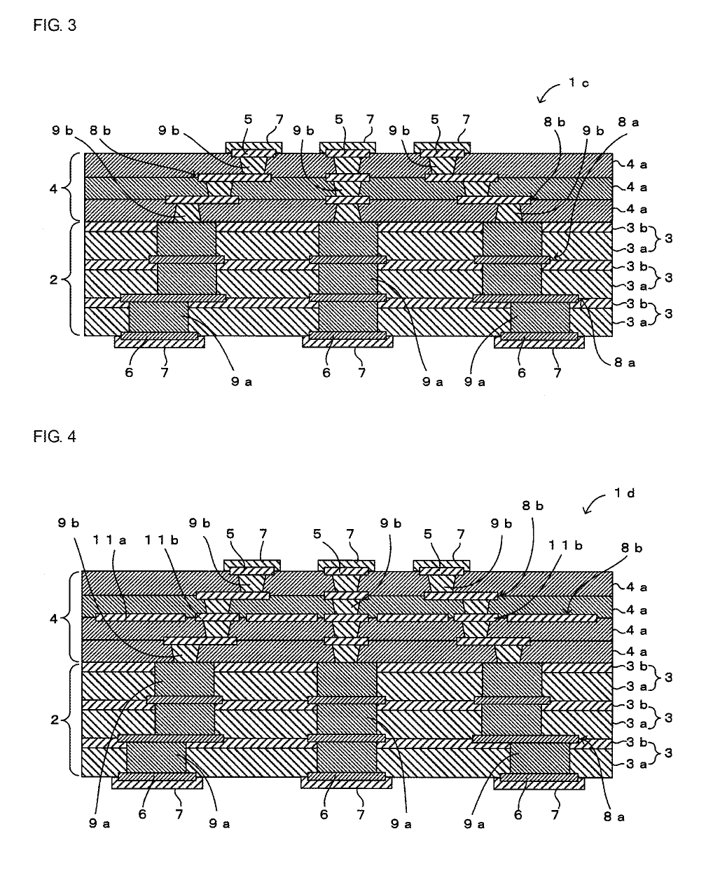

A multilayer circuit board 1c according to Embodiment 3 of the present disclosure is described with reference to FIG. 3. FIG. 3 is a cross-sectional view of the multilayer circuit board 1c.

The difference of the multilayer circuit board 1c according to this embodiment from the multilayer circuit board 1a of Embodiment 1, described with reference to FIG. 1, is that each of the conductive vias 9b in the lowermost resin layer 4a has a larger area at its lower end face, at which it is connected to a conductive via 9a in the uppermost ceramic layer 3, than at its upper end face. The other elements are the same as those in the multilayer circuit board 1a of Embodiment 1 and thus are given the same reference numerals to avoid duplicating description.

This increases the area of connection between the conductive vias 9a in the uppermost ceramic layer 3 and the conductive vias 9b in the lowermost resin layer 4a connected to these conductive vias 9a as compared with that in the multilayer circuit board 1a of Embodiment 1. As a result, the interfacial delamination of the ceramic multilayer body 2 and the resin multilayer body 4 is reduced, and the reliability of the connection between the two sets of conductive vias 9a and 9b is improved at the same time.

### Embodiment 4

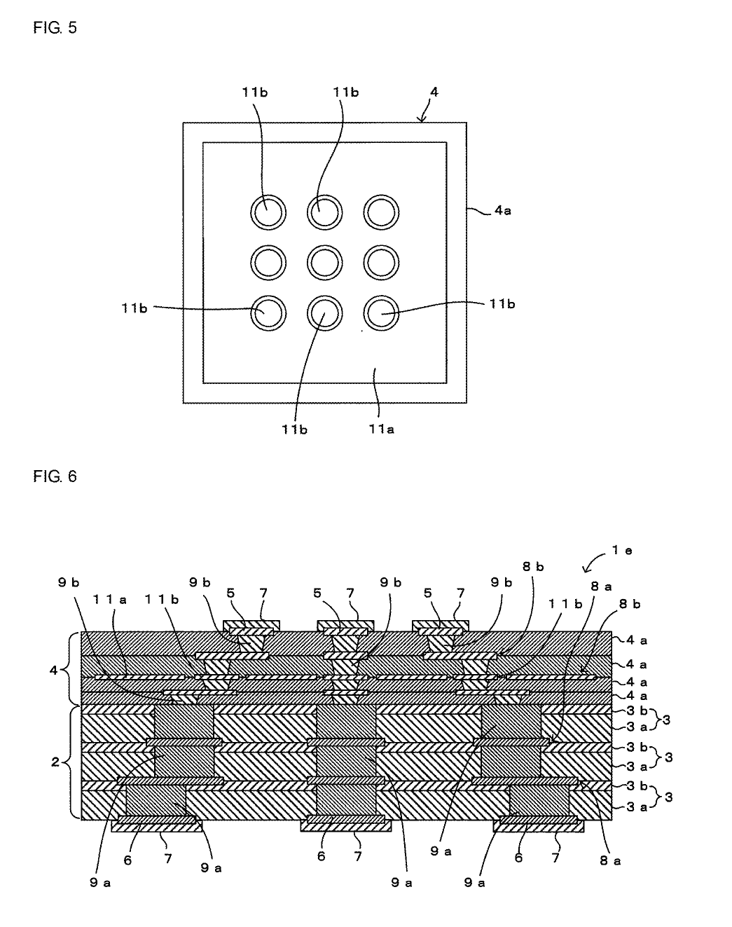

A multilayer circuit board 1d according to Embodiment 4 of the present disclosure is described with reference to FIGS. 4 and 5. FIG. 4 is a cross-sectional view of the multilayer circuit board 1d, and FIG. 5 is a plan view of a predetermined circuit layer 8b.

The difference of the multilayer circuit board 1d according to this embodiment from the multilayer circuit board 1a of Embodiment 1, described with reference to FIG. 1, is that a predetermined circuit layer 8b interposed between two adjacent resin layers 4a has a planar electrode pattern 11a that overlaps the resin multilayer body 4 in plan view except at the periphery of this multilayer body. The other elements are the same as those in the multilayer circuit board 1a of Embodiment 1 and thus are given the same reference numerals to avoid duplicating description.

In this case, the circuit layer 8b positioned substantially in the middle, in the direction of stacking, of the resin multilayer body 4 has wiring electrodes including a planer electrode pattern 11a as a ground electrode and multiple electrode pads 11b that connect predetermined conductive vias 9b formed in the two resin layers 4a touching from above and below, respectively, the circuit layer 8b. The electrode pattern 11a extends, as illustrated in FIG. 5, over a region of the resin multilayer body 4 excluding the periphery and the electrode pads 11b. The electrode pattern 11a overlaps part of the planes of connection between those conductive vias 9b in the lowermost resin layer 4a that are located at each end of the drawing and the corresponding conductive vias 9a in the uppermost ceramic layer 3 in plan view. The electrode pattern 11a may optionally be used as, for example, an electrode for power supply instead of a ground electrode. One planar electrode pattern 11a interposed between any two resin layers 4a of the resin multilayer body 4 will be sufficient.

This embodiment ensures, for example, smaller contraction of the resin multilayer body 4 when an ambient temperature decreases because the coefficient of linear expansion of the planar electrode pattern 11a, made of metal, is smaller than the coefficient of linear expansion of the resin layers 4a. The smaller contraction of the resin multilayer body 4 leads to a decrease in the stress acting on the interface between the ceramic multilayer body 2 and the resin multilayer body 4, thereby reducing the interfacial delamination of the ceramic multilayer body 2 and the resin multilayer body 4.

The stress that acts on the interface between the ceramic multilayer body 2 and the resin multilayer body 4 upon events such as cure shrinkage of the resin multilayer body 4 is proportional to the thickness of the resin multilayer body 4. When a circuit layer 8b having a planar electrode pattern 11a is present between any two of the resin layers 4a of the resin multilayer body 4, the electrode pattern 11a serves to resist the stress the resin layers 4a above the electrode pattern 11a exert on the aforementioned interface. In this case, the stress that acts on the interface is reduced compared with the stress that would occur without the electrode pattern 11a, and this leads to reduced interfacial delamination of the two multilayer bodies 2 and 4. The stress that acts on the interface is relaxed more effectively with smaller total thickness of the resin layers 4a located below the electrode pattern 11a in the resin multilayer body 4. Thus, the circuit layer 8b having the electrode pattern 11a can be on the lower side of the resin multilayer body 4 with respect to the middle in the direction of stacking.

The electrode pattern 11a overlaps part of the planes of connection between those conductive vias 9b in the lowermost resin layer 4a that are located at each end of the drawing and the corresponding conductive vias 9a in the uppermost ceramic layer 3 in plan view. This ensures effective relaxation of the stress that acts on these planes of connection upon events such as cure shrinkage of the resin multilayer body 4.

### Embodiment 5

A multilayer circuit board 1e according to Embodiment 5 of the present disclosure is described with reference to FIG. 6. FIG. 6 is a cross-sectional view of the multilayer circuit board 1e.

The difference of the multilayer circuit board 1e according to this embodiment from the multilayer circuit board 1d of Embodiment 4, described with reference to FIGS. 4 and 5, is that the thickness of the resin layers 4a located below a circuit layer 8b having a planar electrode pattern 11a is smaller than that of the upper resin layers 4a. The other elements are the same as those in Embodiment 4 and thus are given the same reference numerals to avoid duplicating description.

In this configuration, the total thickness of the resin layers 4a located below a circuit layer 8b having an electrode pattern 11a in the resin multilayer body 4 is small. The stress that acts on the interface between the two multilayer bodies 2 and 4 upon events such as cure shrinkage of the resin multilayer body 4 decreases compared with that in the multilayer circuit board 1d according to Embodiment 4. As a result, the interfacial delamination of the two multilayer bodies 2 and 4 is further reduced.

### Embodiment 6

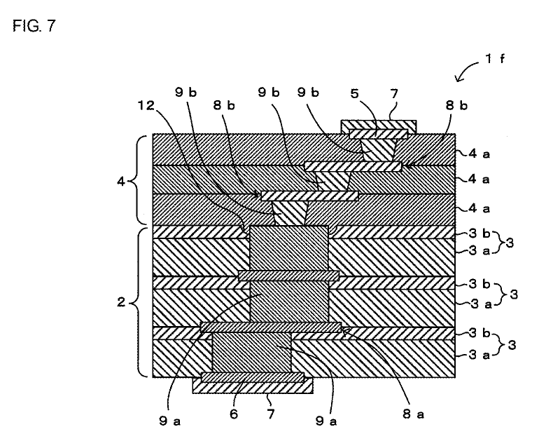

A multilayer circuit board if according to Embodiment 6 of the present disclosure is described with reference to FIG. 7. FIG. 7 is a partial cross-sectional view of the multilayer circuit board if and corresponds to the left half of the multilayer circuit board 1a illustrated in FIG. 1.

The difference of the multilayer circuit board if according to this embodiment from the multilayer circuit board 1a of Embodiment 1, described with reference to FIG. 1, is that there is a gap 12 between the peripheral surface of the upper end portion of each conductive via 9a in the uppermost ceramic layer 3 and this ceramic layer 3 with some amount of the resin of which the lowermost resin layer 4a is made present in the gap 12. The other elements are the same as those in Embodiment 1 and thus are given the same reference numerals to avoid duplicating description.

An example of a process for the creation of the gaps 12 between the conductive vias 9a in the uppermost ceramic layer 3 and this ceramic layer 3 is as follows. First, the uppermost ceramic layer 3 is perforated with via holes for use as conductive vias 9a by laser machining, under conditions that help the glass component of the ceramic layer 3 form glass beads. Through this, relatively large glass beads are formed around the peripheral surfaces of the conductive vias 9a. The top surface of the ceramic multilayer body 2 is then polished, using a relatively rough polisher to create the gaps 12 so that the glass beads around the conductive vias 9a are removed from the surface of the ceramic layer 3 to help creating the gaps 12. Alternatively, polishing under conditions similar to the foregoing with a greater amount of glass contained in the uppermost ceramic layer 3 than in the other ceramic layers 3 also leads to the creation of the gaps 12. The lowermost resin layer 4a is then placed, by spin coating for example, on the ceramic multilayer body 2 with these gaps 12. This forces the resin for the resin layer 4a into these gaps 12.

In this configuration, the anchor effect results from the presence of the resin forming the lowermost resin layer 4a in the gaps 12 between the uppermost ceramic layer 3 and the peripheral surfaces of the upper end portions of the conductive vias 9a in this ceramic layer 3, and improves the strength of the adhesion between the ceramic multilayer body 2 and the resin multilayer body 4 at their interface. As a result, the interfacial delamination of the two multilayer bodies 2 and 4 is reduced.

### Embodiment 7

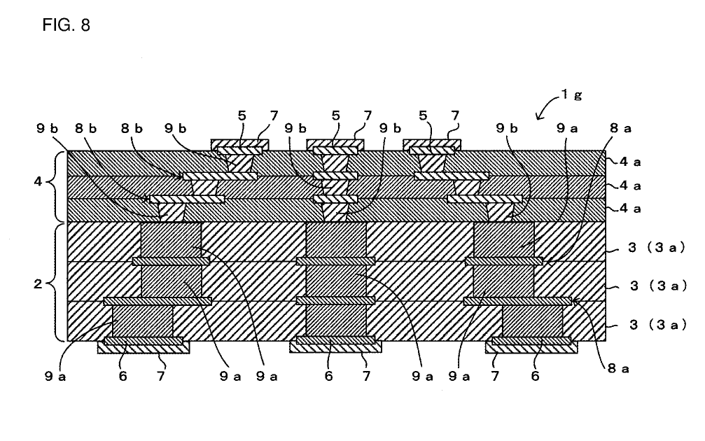

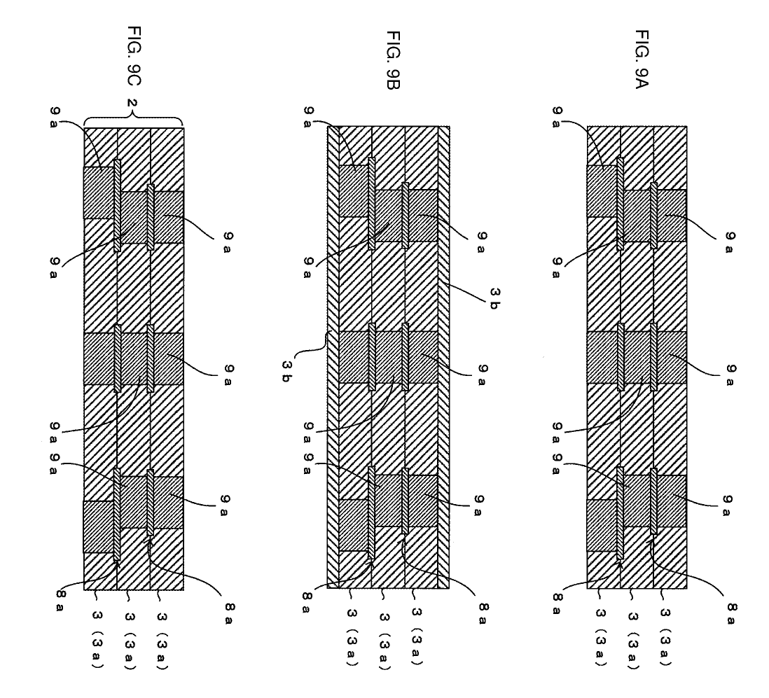

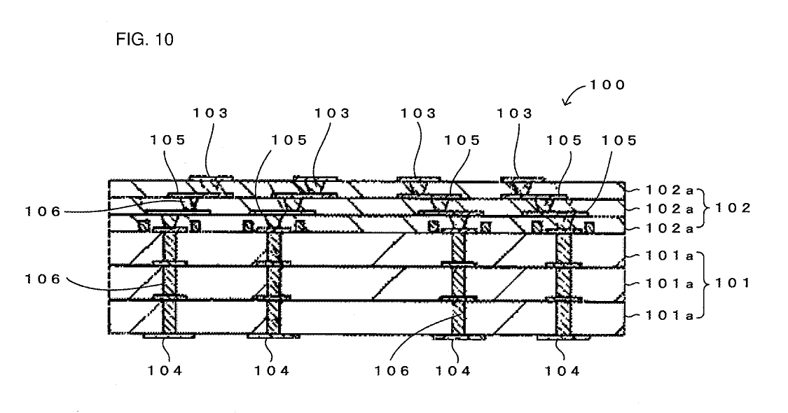

A multilayer circuit board 1g according to Embodiment 7 of the present disclosure is described with reference to FIGS. 8 and 9. FIG. 8 is a cross-sectional view of the multilayer circuit board 1g, and FIGS. 9A-9C present diagrams for illustrating a method for the production of the ceramic multilayer body 2 of the multilayer circuit board 1g.

The difference of the multilayer circuit board 1g according to this embodiment from the multilayer circuit board 1a of Embodiment 1, described with reference to FIG. 1, is that each of the ceramic layers 3 of the ceramic multilayer body 2 is merely a substrate layer 3a. The other elements are the same as those in the multilayer circuit board 1a of Embodiment 1 and thus are given the same reference numerals to avoid duplicating description.

In this case, the process for the production of the ceramic multilayer body 2 is as follows. First, a low-temperature co-fired ceramic is formed into multiple ceramic green sheets made of (substrate layers 3a). Each of the ceramic green sheets (substrate layers 3a) is perforated with through-holes, using a laser for example, at the points where conductive vias 9a are to be formed. After the formation of the conductive vias 9a in a known method a circuit layer 8a having wiring electrodes is formed, such as by screen printing using a conductor paste that contains metal, e.g., Ag or Cu.

Then, as illustrated in FIG. 9A, the ceramic green sheets (substrate layers 3a) with conductive vias 9a and a circuit layer 8a are stacked.

Then, as illustrated in FIG. 9B, an anti-shrink layer 3b that does not sinter at the sintering temperature of the ceramic green sheets (substrate layers 3a) is placed on the top and bottom surfaces of the stack of the substrate layers 3a. Specifically, an anti-shrink layer 3b in the form of paste in which the major component is a flame-retardant powder, such as a powder of alumina or zirconia, is placed on and pressure-bonded to the top and bottom surfaces of the stack of the ceramic green sheets (substrate layers 3a), and the laminate is fired in the constrained state at 800° C. to 1000° C. The laminate may be fired with pressure on the ceramic green sheets (substrate layers 3a) through the anti-shrink layers 3b (pressure firing) or without pressure (pressureless firing).

With or without pressure, the anti-shrink layers 3b on the top and bottom surfaces of the stack of ceramic green sheets (substrate layers 3a) do not sinter unless they are heated to, for example, 1500° C. or more. Firing at 800° C. to 1000° C. therefore leaves the anti-shrink layers 3b unsintered. During firing, however, the resin binder in the anti-shrink layers 3b thermally decomposes and splashes, leaving a ceramic powder. Thus, the anti-shrink layers 3b (ceramic powder) adhering to the top and bottom surfaces of the stack of ceramic green sheets (substrate layers 3a) are removed, by wet blasting (water jetting) or buffing for example (FIG. 9C). This completes the ceramic multilayer body 2. Bottom electrodes 6 and Ni/Au electrodes 7 are then formed in the same way as in the production of the multilayer circuit board 1a according to Embodiment 1. The resin multilayer body 4 is also formed in the same way as in Embodiment 1, completing the multilayer circuit board 1g.

This configuration provides advantages similar to those of the multilayer circuit board 1a according to Embodiment 1. The method according to this embodiment for the formation of the ceramic multilayer body 2, furthermore, does not cause the stack of ceramic green sheets to contract in the direction of its main surfaces during sintering. The stack rather expands in the direction of its main surfaces, and this limits variations in the dimensions of the fired ceramic multilayer body 2. The high pressure applied further planarizes the stack of ceramic green sheets that has yet to be fired, leading to reduced warpage and improved planarity of the fired ceramic multilayer body 2. Limiting variations in the dimensions of the ceramic multilayer body 2 in this way ensures improved dimensional accuracy.

The present disclosure is not limited to the above embodiments. Besides the foregoing, various changes are possible unless they constitute departures from the gist of the disclosure. For example, the number of layers in each ceramic layer 3 and that in each resin layer 4a can optionally be changed.

### INDUSTRIAL APPLICABILITY

The present disclosure is applicable to various multilayer circuit boards that include a ceramic multilayer body that is a stack of multiple ceramic layers and a resin multilayer body on the ceramic multilayer body that is a stack of multiple resin layers.

### REFERENCE SIGNS LIST

1a to 1g Multilayer circuit board
2 Ceramic multilayer body
3 Ceramic layer
4 Resin multilayer body
4a Resin layer
8b Circuit layer
9a Conductive via (first interlayer coupling conductor)
9b Conductive via (second interlayer coupling conductor)
10 Electrode pad
11a Electrode pattern
12 Gap

1. A multilayer circuit board comprising:
a ceramic multilayer body comprising a stack of a plurality of ceramic layers;
a resin multilayer body on the ceramic multilayer body, the resin multilayer body comprising a stack of a plurality of resin layers;
a first interlayer coupling conductor in an uppermost one of the ceramic layers, an upper end face thereof being exposed on an interface between the ceramic and resin multilayer bodies; and
a second interlayer coupling conductor in a lowermost one of the resin layers, a lower end face thereof being exposed on the interface between the ceramic and resin multilayer bodies and directly connected to the upper end face of the first interlayer coupling conductor,
wherein the lower end face of the second interlayer coupling conductor is within the upper end face of the first interlayer coupling conductor in plan view.

2. The multilayer circuit board according to claim 1, further comprising a circuit layer between any two of the resin layers, the circuit layer having a planar electrode pattern that overlaps the resin multilayer body in plan view except at a periphery of the resin multilayer body.

3. The multilayer circuit board according to claim 2, wherein a thickness of the lowermost one of the resin layers is smaller than a thickness of one or more layers of the plurality of resin layers located above the circuit layer.

4. The multilayer circuit board according to claim 1, wherein:
there is a gap between a peripheral surface of an upper end portion of the first interlayer coupling conductor and the uppermost ceramic layer; and
a resin of which the lowermost one of the resin layers is made is present in the gap.

5. The multilayer circuit board according to claim 1, further comprising an electrode pad connected to an upper end face of the second interlayer coupling conductor, wherein
the electrode pad has a larger area than the upper end face of the first interlayer coupling conductor so that the upper end face of the first interlayer coupling conductor is within the electrode pad in plan view.

6. The multilayer circuit board according to claim 1, wherein a largest width of the lower end face of the second interlayer coupling conductor is greater than a thickness of the lowermost one of the resin layers.

7. The multilayer circuit board according to claim 1, wherein the second interlayer coupling conductor has a larger area at the lower end face thereof than at an upper end face thereof.

8. A probe card comprising the multilayer circuit board according to claim 1, wherein the probe card tests an electrical characteristic of a semiconductor device.

9. The multilayer circuit board according to claim 2, wherein:
there is a gap between a peripheral surface of an upper end portion of the first interlayer coupling conductor and the uppermost ceramic layer; and
a resin of which the lowermost one of the resin layers is made is present in the gap.

10. The multilayer circuit board according to claim 3, wherein:
there is a gap between a peripheral surface of an upper end portion of the first interlayer coupling conductor and the uppermost ceramic layer; and
a resin of which the lowermost one of the resin layers is made is present in the gap.

11. The multilayer circuit board according to claim 2, further comprising an electrode pad connected to an upper end face of the second interlayer coupling conductor, wherein
the electrode pad has a larger area than the upper end face of the first interlayer coupling conductor so that the upper end face of the first interlayer coupling conductor is within the electrode pad in plan view.

12. The multilayer circuit board according to claim 3, further comprising an electrode pad connected to an upper end face of the second interlayer coupling conductor, wherein
the electrode pad has a larger area than the upper end face of the first interlayer coupling conductor so that the upper end face of the first interlayer coupling conductor is within the electrode pad in plan view.

13. The multilayer circuit board according to claim 4, further comprising an electrode pad connected to an upper end face of the second interlayer coupling conductor, wherein
the electrode pad has a larger area than the upper end face of the first interlayer coupling conductor so that the upper end face of the first interlayer coupling conductor is within the electrode pad in plan view.

14. The multilayer circuit board according to claim 2, wherein a largest width of the lower end face of the second interlayer coupling conductor is greater than a thickness of the lowermost one of the resin layers.

15. The multilayer circuit board according to claim 3, wherein a largest width of the lower end face of the second interlayer coupling conductor is greater than a thickness of the lowermost one of the resin layers.

16. The multilayer circuit board according to claim 4, wherein a largest width of the lower end face of the second interlayer coupling conductor is greater than a thickness of the lowermost one of the resin layers.

17. The multilayer circuit board according to claim 5, wherein a largest width of the lower end face of the second interlayer coupling conductor is greater than a thickness of the lowermost one of the resin layers.

18. The multilayer circuit board according to claim 2, wherein the second interlayer coupling conductor has a larger area at the lower end face thereof than at an upper end face thereof.

19. The multilayer circuit board according to claim 3, wherein the second interlayer coupling conductor has a larger area at the lower end face thereof than at an upper end face thereof.

20. The multilayer circuit board according to claim 4, wherein the second interlayer coupling conductor has a larger area at the lower end face thereof than at an upper end face thereof.
